(19) United States
(12) Patent Application Publication
(10) Pub. No.: US 2002/0105371 A1
(43) Pub. Date: Aug. 8, 2002

(54) Inverter circuit

(75) Inventor: Kazuo Nakaizumi, Kawasaki-shi (JP)

Correspondence Address: DARBY & DARBY P.C., 805 Third Avenue, New York, NY, 10022, US

(73) Assignee: Ando Electric Co., Ltd.

(21) Appl. No.: 10/066,819

(22) Filed: Feb. 4, 2002

(30) Foreign Application Priority Data
Feb. 7, 2001 (JP) P2001-030788

(51) Int. Cl. H03K 17/16

(52) U.S. Cl. 327/391

(57) ABSTRACT

An inverter circuit suitable for use in a highly accurate measuring device such as an LSI tester provides a D flip-flop in addition to unit inverters and switching circuits, each of which contains a pair of a PMOS transistor and an NMOS transistor. The switching circuits are arranged in relation to the unit inverters that are connected together in a cascade connection manner. A clock signal (CLK1) consisting of clock pulses having a variable frequency is input to the unit inverter, while another clock signal (CLK3) having a constant frequency is input to the D flip-flop to produce a prescribed clock signal (CLK2, CLK4), which is continuously supplied to the switching circuits even when no clock pulse is input to the unit inverter. Thus, it is possible to avoid unwanted variations of junction temperature and response time (e.g., jitter).

### BACKGROUND OF THE INVENTION

1. Field of the Invention This invention relates to inverter circuits particularly for use in highly accurate measuring devices such as LSI testers.

2. Description of the Related Art

Recently, a variety of electronic devices have been using ICs and LSI devices, in which integrated circuits are frequently composed of CMOS circuits (where “CMOS” stands for “Complementary Metal Oxide Semiconductor”) in order to reduce electric power consumption. A typical example of an inverter circuit using CMOS circuits is composed of p-channel transistors and n-channel transistors. FIG. 5 shows an example of the CMOS-type inverter circuit. That is, an inverter circuit 10 is a combination of unit inverters 20a, 20b, . . . , which are combined together in a cascade connection manner. Normally, several tens of the unit inverters are connected together in a cascade connection manner to form the inverter circuit.

The unit inverter 20a has a p-channel MOS transistor (hereinafter, referred to as a PMOS transistor) 21 a and an n-channel MOS transistor (hereinafter, referred to as an NMOS transistor) 22a. Both the gate electrode of the PMOS transistor 21a and the gate electrode of the NMOS transistor 22a are connected to an input terminal 23a.

Both the drain electrode of the PMOS transistor 21a and the source electrode of the NMOS transistor 22a are connected to an output terminal 24a. In addition, the source electrode of the PMOS transistor 21a is connected to a power source (Vcc), and the drain electrode of the NMOS transistor 22a is grounded.

The unit inverter 20b is formed similarly to the unit inverter 20a. Specifically, the unit inverter 20b has a PMOS transistor 21b and an NMOS transistor 22b. Both the gate electrode of the PMOS transistor 21b and the gate electrode of the NMOS transistor 22b are connected to an input terminal 23b. Both the drain electrode of the PMOS transistor 21b and the source electrode of the NMOS transistor 22b are connected to an output terminal 24b. In addition, the source electrode of the PMOS transistor 21b is connected to the power source (Vcc), and the drain electrode of the NMOS transistor 22b is grounded.

The aforementioned unit inverters 20a and 20b are combined together in a cascade connection manner such that the output terminal 24a is connected to the input terminal 23b.

Next, the operation timings of the inverter circuit 10 shown in FIG. 5 will be described with reference to the time charts shown in FIGS. 6A to 6D. A clock signal CLK1 shown in FIG. 6A is input to the input terminal 23a of the unit inverter 20a. Herein, it is possible to vary the frequency of the clock signal CLK1 by units of a minimal period. For example, the minimal period (or minimal cycle) of the clock signal CLK1 is approximately set in a range from 2 ns to 10 ns.

FIG. 6B shows a transient current I₁ such as a charging current, discharging current, and through current that flows in the unit inverter 20a every time the PMOS transistor 21a and the NMOS transistor 22a are switched over; FIG. 6C shows a junction temperature tⱼ; and FIG. 6D shows a time difference t_{pd} measured between the input signal and the output signal of the inverter circuit 10 shown in FIG. 7. In other words, the reference symbol t_{pd} designates the response time of the inverter circuit 10.

During the time period between time t₃₁ and t₃₄, the clock signal CLK1 is increased in frequency. Therefore, clock pulses are sequentially input to the unit inverter 20a at the minimal periods (T1), each of which approximately ranges from 2 ns to 10 ns. During the aforementioned time period between time t₃₁ and time t₃₄, the PMOS transistor 21a and the NMOS transistor 22a repeat switching operations at a high speed. As a result, an average current I_{AV}, which is an average of the transient current I₁ shown in FIG. 6B during the aforementioned time period, flows across both the PMOS transistor 21a and the NMOS transistor 22a.

In the above, the junction temperature tⱼ (see FIG. 6C) that is initially set to 25° C. is gradually increased to 75° C. due to clock pulses sequentially input to the unit inverter 20a. Accordingly, the response time t_{pd} (see FIG. 6D) that is initially set to 1600 ps is increased to 2000 ps due to clock pulses sequentially input to the unit inverter 20a. FIGS. 6C and 6D show that the junction temperature t_{pd} becomes 75° C., and the response time t_{pd} becomes 2000 ps while the PMOS transistor 21a and the NMOS transistor 22a perform high-speed switching operations. These values are merely examples and are not restrictive, and could be easily varied by heat radiation or dissipation using a heatsink, for example.

During the time period T2 between time t₃₄ and time t₃₅, the clock signal CLK1 is decreased in frequency, wherein only a single clock pulse may be input to the unit inverter 20a within 10 ms, for example. During this time period T2, both the PMOS transistor 21a and the NMOS transistor 22a perform a switching operation one time. Therefore, substantially no transient current flows across the PMOS transistor 21a and the NMOS transistor 22a. For this reason, the junction temperature tⱼ that was increased to 75° C. at time t₃₄ is decreased to 25° C., which is the initial junction temperature of the inverter circuit 10 when input the clock signal CLK1 is not input. Accordingly, the response time t_{pd} that was increased to 2000 ps at time t₃₄ is decreased to 1600 ps, which is the initial response time of the inverter circuit 10 when the clock signal CLK1 is not input.

During the high-speed operation period (e.g., the foregoing time period between time t₃₁ and t₃₄ shown in FIGS. 6A to 6D), the transient current flows across the PMOS transistor 21a and the NMOS transistor 22a in the unit inverter 20a. In contrast, during the low-speed operation period (e.g., the time period between time t₃₄ and time t₃₅), substantially no transient current flows across the transistors 21a and 22a in the unit inverter 20a. The unit inverter 20b operates similarly to the unit inverter 20a.

Therefore, the unit inverter 20a may cause dispersions in electric power consumption in response to the frequency of the clock signal CLK1. For this reason, a temperature difference of 50° C. is caused with respect to the junction temperature tⱼ between the high-speed operation period and low-speed operation period. In addition, a response time difference of 400 ps is caused with respect to the response time t_{pd} between the high-speed operation period and low-speed operation period.

The aforementioned response time difference causes jitter. In a highly accurate measuring device such as an LSI tester, it is necessary to reduce the jitter so as to be not greater than 200 ps in conformity with the requirements of the prescribed standard. However, the aforementioned inverter circuit, which causes relatively large jitter, may be inappropriate for use in a highly accurate measuring device.

### SUMMARY OF THE INVENTION

It is an object of the invention to provide an inverter circuit that causes substantially no variations in junction temperature and jitter even though the clock frequency is varied. Hence, the inverter circuit of this invention is designed to be suitable for use in a highly accurate measuring device.

An inverter circuit of this invention is designed to be suitable for use in a highly accurate measuring device such as an LSI tester. Specifically, the inverter circuit comprises unit inverters, switching circuits, and a D flip-flop. All of the unit inverters and switching circuits comprise a pair of a PMOS transistor and an NMOS transistor. Additionally, the switching circuits are arranged relative to the unit inverters that are connected together in a cascade connection manner.

In the above, a clock signal (CLK1) consisting of clock pulses having a variable frequency is input to the unit inverter, while another clock signal (CLK3) having a constant frequency is input to the D flip-flop to produce a prescribed clock signal (CLK2, CLK4). Thus, the D flip-flop is capable of continuously supplying the prescribed clock signal to the switching circuits even when no clock pulse is input to the unit inverter. Thus, it is possible to avoid unwanted variations of junction temperature and response time (e.g., jitter).

Various configurations for the D flip-flop and switching circuits are provided. According to a first configuration, the gate electrode of the PMOS transistor is grounded, and the inverted output of the D flip-flop is supplied to the gate electrode of the NMOS transistor. According to a second configuration, the output of the D flip-flop is supplied to the gate electrode of the PMOS transistor, and a power voltage (Vcc) is applied to the gate electrode of the NMOS transistor. According to a third configuration, the output of the D flip-flop is supplied to the gate electrode of the PMOS transistor, and the inverted output is supplied to the gate electrode of the NMOS transistor.

### BRIEF DESCRIPTION OF THE DRAWINGS

These and other objects, aspects, and embodiments of the present invention will be described in more detail with reference to the following drawing figures, in which:

FIG. 1 is a circuit diagram showing a configuration of an inverter circuit in accordance with a first embodiment of the invention;

FIG. 2A is a time chart showing a clock signal CLK1 input to a unit inverter of the inverter circuit;

FIG. 2B is a time chart showing a clock signal CLK3 input to a D flip-flop provided in the inverter circuit;

FIG. 2C is a time chart showing a clock signal CLK2 output from the D flip-flop in the inverter circuit:

FIG. 2D is a time chart showing a transient current I₁ flowing in the unit inverter of the inverter circuit;

FIG. 2E is a time chart showing a switching current I₂ flowing a switching circuit of the inverter circuit;

FIG. 2F is a time chart showing a total current I_{T} that is the sum of the average of the transient current I₁ and the average of the switching current I₂;

FIG. 2G is a time chart showing a junction temperature tⱼ measured in the inverter circuit;

FIG. 2H is a time chart showing a response time t_{pd} of the inverter circuit;

FIG. 3 is a block diagram showing a configuration of an inverter circuit in accordance with a second embodiment of the invention;

FIG. 4 is a block diagram showing a configuration of an inverter circuit in accordance with a third embodiment of the invention;

FIG. 5 is a circuit diagram showing an inverter circuit that comprises unit inverters in a cascade connection manner;

FIG. 6A is a time chart showing a clock signal CLK1 consisting of clock pulses, which are changed in frequency over time;

FIG. 6B is a time chart showing a transient current I₁ flowing across transistors performing switching operations;

FIG. 6C is a time chart showing variations of a junction temperature tⱼ measured for the inverter circuit shown in FIG. 5;

FIG. 6D is a time chart showing variations of a response time t_{pd} of the inverter circuit shown in FIG. 5; and

FIG. 7 is a simplified block diagram showing the inverter circuit shown in FIG. 5.

### DESCRIPTION OF THE PREFERRED EMBODIMENTS

This invention will be described in further detail by way of examples with reference to the accompanying drawings.

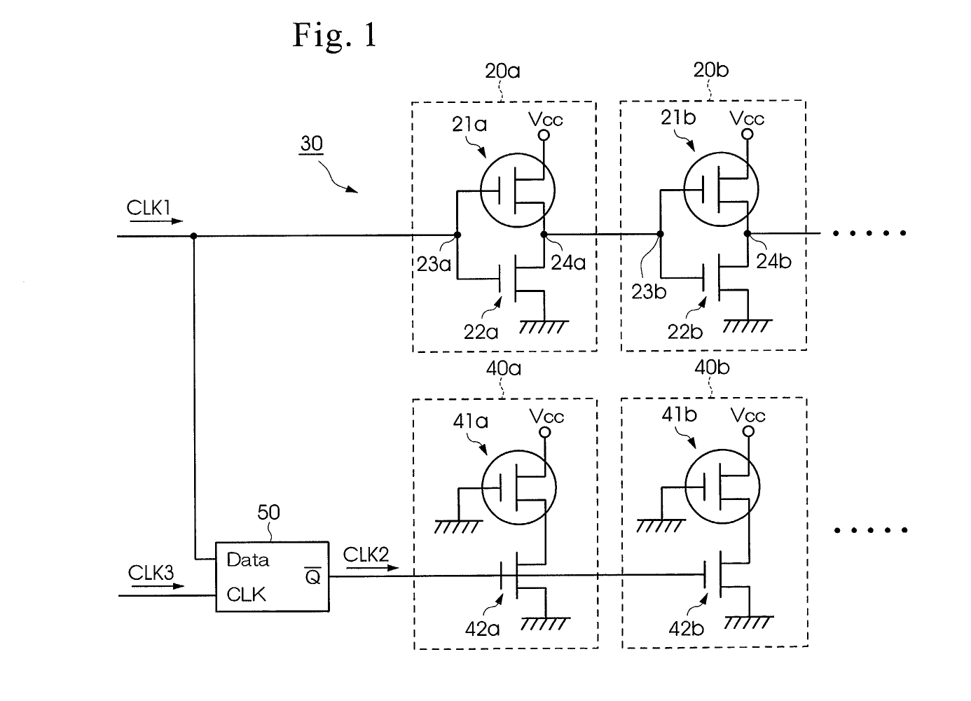

FIG. 1 is a circuit diagram showing a configuration of an inverter circuit in accordance with a first embodiment of the invention. That is, an inverter circuit 30 shown in FIG. 1 is composed of unit inverters 20a and 20b that are combined together in a cascade connection manner as well as switching circuits 40a and 40b, and a D flip-flop 50. The switching circuits 40a and 40b are provided relative to the unit inverters 20a and 20b respectively. The D flip-flop 50 produces pulses to be supplied to the switching circuits 40a and 40b that are connected in series.

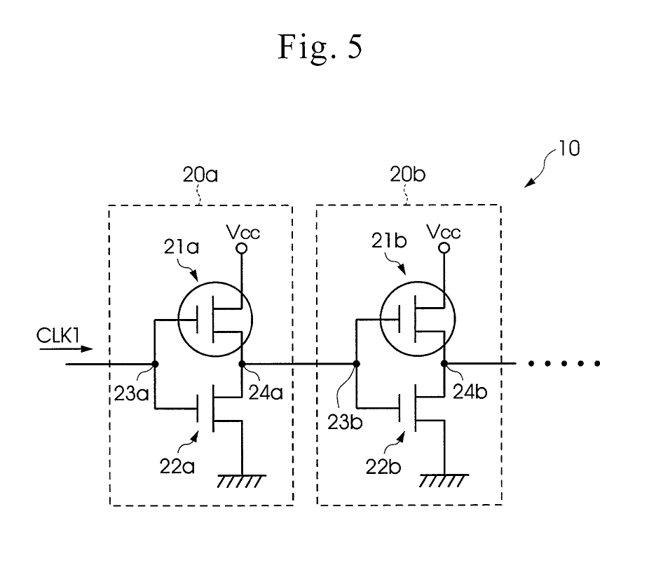

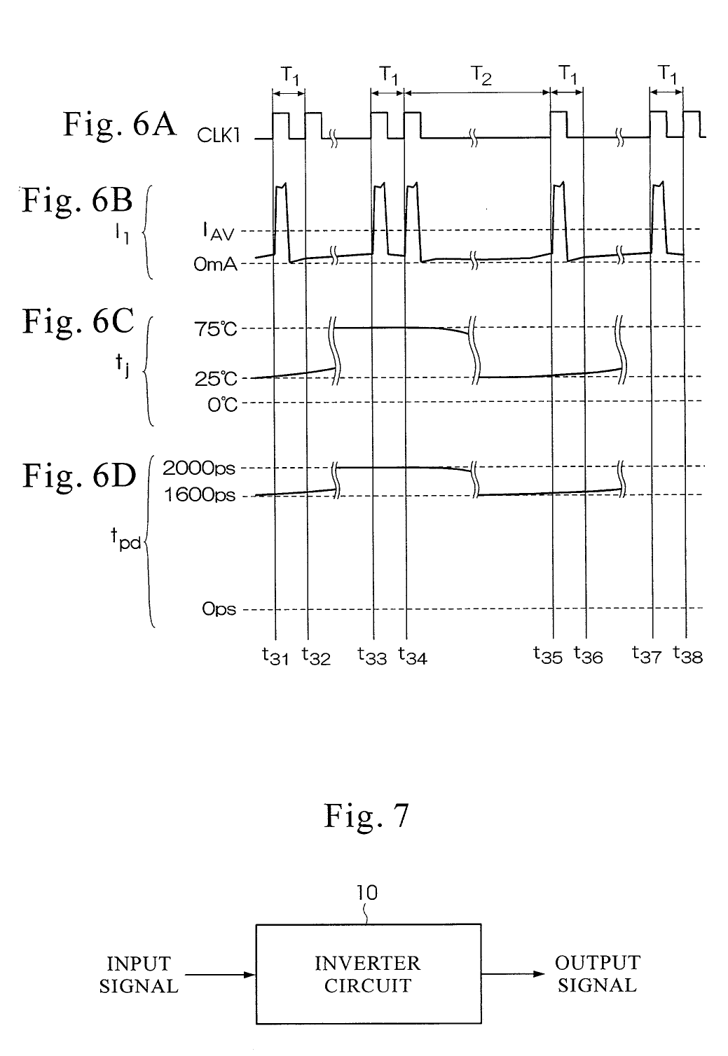

The unit inverters 20a and 20b shown in FIG. 1 are identical to the foregoing ones shown in FIG. 5, wherein parts identical to those shown in FIG. 5 are designated by the same reference numerals; hence, the description thereof will be omitted. A clock signal CLK1 is input to the unit inverter 20a shown in FIG. 1 similarly to FIG. 5. The switching circuits 40a and 40b are formed in proximity to the unit inverters 20a and 20b respectively. This is because it is necessary to avoid an unwanted reduction of the junction temperature when the clock signal CLK1 is not input to the unit inverters 20a and 20b for a long time, which may range from several milliseconds to several tens of milliseconds, for example. That is, when the clock signal CLK1 is not input to the unit inverters 20a and 20b for a long time, the inverter circuit 30 avoids an unwanted reduction of the junction temperature by forcing current to flow through the switching circuits 40a and 40b respectively.

The switching circuit 40a has a PMOS transistor 41a and an NMOS transistor 42a. Herein, the drain electrode of the PMOS transistor 41a is connected to the source electrode of the NMOS transistor 42a. The source electrode of the PMOS transistor 41 a is connected to a power source (Vcc), and the drain electrode of the NMOS transistor 42a is grounded. In addition, the gate electrode of the PMOS transistor 41a is grounded, so that the PMOS transistor 41a functions as a load resistance for the NMOS transistor 42a. The D flip-flop 50 is connected to the gate electrode of the NMOS transistor 42a. That is, the D flip-flop 50 is provided to make current flow through the NMOS transistor 42a when the clock signal CLK1 is not input to the unit inverters 20a and 20b for a long time.

The D flip-flop 50 has a data input terminal (Data) and a clock input terminal (CLK) as well as an inverted output terminal (\overline{Q}). That is, the clock signal CLK1 is input to the data input terminal; a clock signal CLK3 is input to the clock input terminal; and a clock signal CLK2 is output from the inverted output terminal. The inverted output (namely, CLK2) of the D flip-flop 50 is supplied to the gate electrode of the NMOS transistor 42a. The switching circuit 40b has a configuration similar to that of the switching circuit 40a and is composed of a PMOS transistor 41b and an NMOS transistor 42b. The clock signal CLK3 has the minimal clock period and consists of clock pulses that appear at a constant rate.

Generally speaking, the sizes of transistors are defined by the gate widths thereof. In FIG. 1, the sizes of the PMOS transistors 41a and 41b provided in the switching circuits 40a and 40b are set ‘1/n’ times smaller than the sizes of the PMOS transistors 21a and 21b provided in the unit inverters 20a and 20b, wherein ‘n’ is a natural number arbitrarily selected. Similarly, the sizes of the NMOS transistors 42a and 42b provided in the switching circuits 40a and 40b are set ‘1/n’ times smaller than the sizes of NMOS transistors 22a and 22b provided in the unit inverters 20a and 20b. The aforementioned setting for the sizes of the PMOS and NMOS transistors is required in order to match the average current flowing through the unit inverters 20a and 20b with the average current flowing through the switching circuits 40a and 40b. If the same size is set for all the transistors in the unit inverters 20a and 20b as well as the switching circuits 40a and 40b, for example, it may be assumed that the current flowing through the switching circuits 40a and 40b is increased ‘n’ times larger than the current flowing through the unit inverters 20a and 20b.

The present embodiment is designed to provide the switching circuits 40a and 40b relative to the unit inverters 20a and 20b respectively. That is, the present embodiment avoids an unwanted reduction of the junction temperature by forcing current to flow through the switching circuits 40a and 40b even when no current flows through the unit inverters 20a and 20b for a long time. For this reason, if the average current flowing through the unit inverters 20a and 20b differs from the average current flowing through the switching circuits 40a and 40b, the junction temperature should be varied, and therefore, the original object of this invention cannot be achieved. Specifically, the present embodiment regulates the sizes of the transistors in such a manner that the average current which flows through the unit inverters 20a and 20b performing high-speed switching operations substantially matches the average current which flows through the switching circuits 40a and 40b when substantially no current flows through the unit inverters 20a and 20b. Thus, it is possible to avoid an unwanted reduction of the junction temperature.

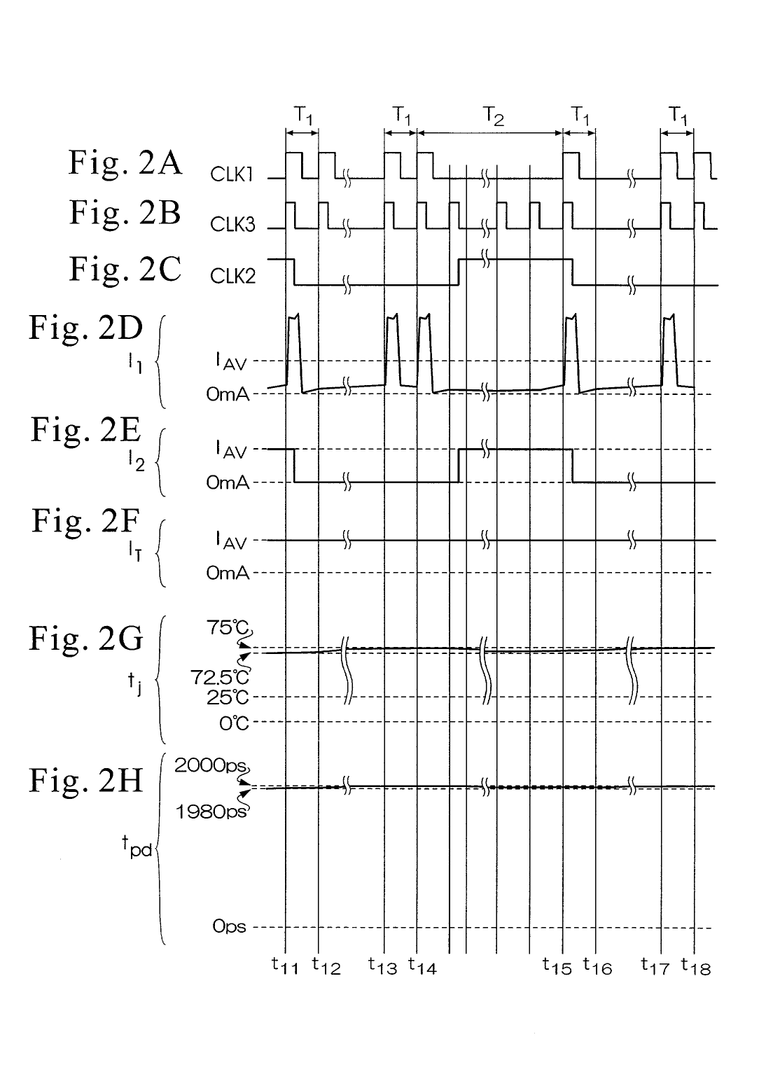

Next, the operations of the inverter circuit 30 of the present embodiment will be described in detail with reference to FIGS. 2A to 2H, which show the operation timings of the inverter circuit 30. In FIG. 1, the clock signal CLK1 is input to an input terminal 23a of the unit inverter 20a. Similar to the aforementioned inverter circuit 10 shown in FIG. 5, the inverter circuit 30 shown in FIG. 1 inputs the clock signal CLK1 whose frequency can be changed in units of one cycle. The minimal period of the clock signal CLK1 ranges from 2 ns to 10 ns, for example. In addition, the clock signal CLK3 input to the D flip-flop 50 has the aforementioned minimal period and consists of clock pulses that appear at a constant rate.

FIGS. 2A, 2B, and 2C show the clock signals CLK1, CLK3, and CLK2 respectively. FIG. 2D shows a transient current I₁ (e.g., charging current, discharging current, and through current) that flows through the PMOS transistor 21a and the NMOS transistor 22a which perform switching operations in the unit inverter 20a. FIG. 2E shows a switching current I₂ that flows through the PMOS transistor 41a and the NMOS transistor 42a which perform switching operations in the switching circuit 40a. FIG. 2F shows a total current I_{T} that is the sum of the average of the transient current I₁ and the average of the switching current I₂. FIG. 2G shows a junction temperature tⱼ; and FIG. 2H shows a response time t_{pd} of the inverter circuit 30. Definitions of the junction temperature tⱼ and the response time t_{pd} have already been described with reference to FIG. 7.

During the time period between time t₁₁, and t₁₄, the clock signal CLK1 is increased in frequency, that is, the minimal period thereof ranges from 2 ns to 10 ns, for example. Hence, clock pulses of the clock signal CLK1 are sequentially input to the unit inverter 20a in respective cycles corresponding to the aforementioned minimal period. Hence, the PMOS transistor 21a and the NMOS transistor 22a repeat switching operations at a high speed, so that an average transient current I_{AV} (see FIG. 2D) flows through the PMOS transistor 21a and the NMOS transistor 22a in the unit inverter 20a during the time period between t₁₁ and t₁₄. In this time period, the junction temperature tⱼ is increased to 75° C. (see FIG. 2G), and the response time t_{pd} becomes 2000 ps (see FIG. 2H). The present embodiment describes an example wherein the junction temperature tⱼ becomes 75° C., and the response time t_{pd} becomes 2000 ps while the PMOS transistor 21a and the NMOS transistor 22a perform switching operations at a high speed. Of course, these values may be easily varied by providing heat radiation or dissipation using a heatsink and the like.

During the next time period T2 between time t₁₄ and time t₁₅, the clock signal CLK1 is decreased in frequency. Hence, only one clock pulse is input to the unit inverter 20a during the prescribed time of about 10 ms. That is, each of the PMOS transistor 21a and the NMOS transistor 22a performs a switching operation one time during the time period T2 between time t₁₄ and time t₁₅. Hence, substantially no transient current flows through the PMOS transistor 21a and the NMOS transistor 22a.

As for the D flip-flop 50, the clock signal CLK1 is input to the data input terminal (Data), and the ‘constant’ clock signal CLK3 is also input to the clock input terminal (CLK). When the clock signal CLK1 is low for two cycles or more corresponding to the minimal period set for the clock signal CLK3, the clock signal CLK2 output from the inverted output terminal of the D flip-flop 50 becomes high (see FIG. 2C). The high level of the clock signal CLK2 is maintained for a while until the next clock pulse of the clock signal CLK1 is input to the unit inverter 20a. During the high level period of the clock signal CLK2, both of the NMOS transistors 42a and 42b in the switching circuits 40a and 40b are turned ON, so that the average switching current I_{AV} (see FIG. 2E) flows through the PMOS transistors 41a and 41b, and through the NMOS transistors 42a and 42b in the switching circuits 40a and 40b.

As described above, even though no current flows through the unit inverters 20a and 20b for a long time, the average switching current I_{AV} is forced to flow through the switching circuits 40a and 40b. For this reason, substantially no variations occur in the junction temperature tⱼ; actually, it may be observed from FIG. 2G that a small reduction of 2.5° C. occurs in the junction temperature tⱼ due to disparities of the sizes of the transistors and manufacturing errors. Since substantially no variations occur in the junction temperature Tⱼ substantially no variations occur in the response time t_{pd}; actually, it may be observed from FIG. 2H that a small reduction of 20 ps occurs in the response time t_{pd}. In summary, the inverter circuit of the present embodiment operates in a stable manner in terms of the junction temperature and response time, regardless of the operations of the unit inverters.

As described above, the present embodiment provides the switching circuits 40a and 40b relative to the unit inverters 20a and 20b so that the prescribed current is forced to flow through the switching circuits 40a and 40b even when the clock signal CLK1 is not input to the unit inverters 20a and 20b for a long time. Thus, it is possible to avoid unwanted variations of the junction temperature tⱼ and unwanted variations of the response time t_{pd} which may cause jitter. In summary, the present embodiment provides an inverter circuit which is suitable for use in a highly accurate measuring device.

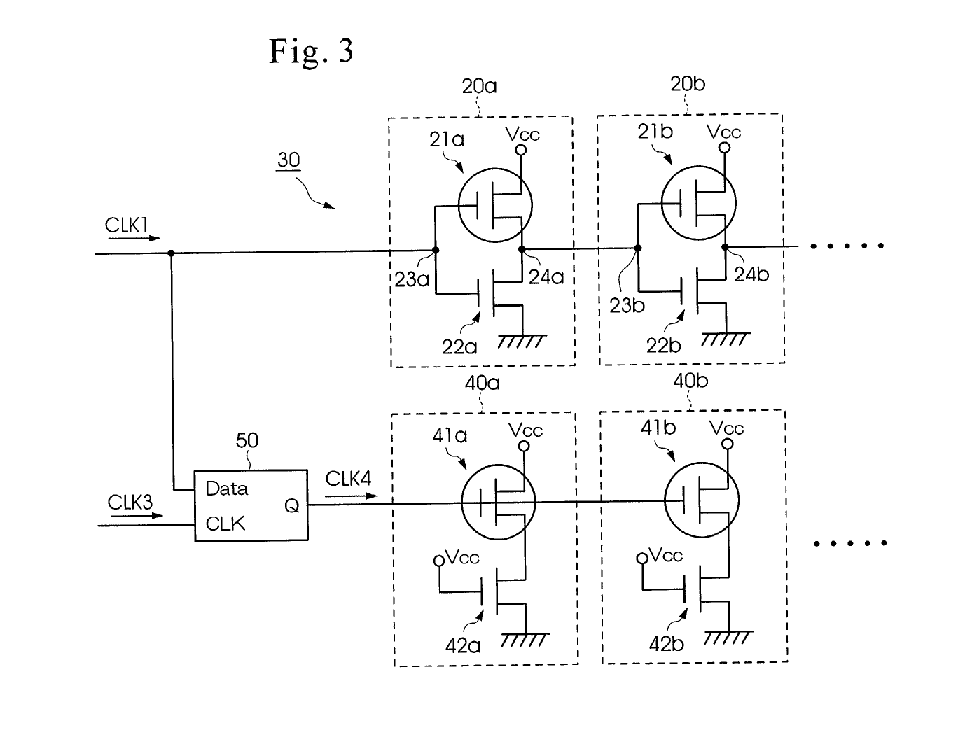

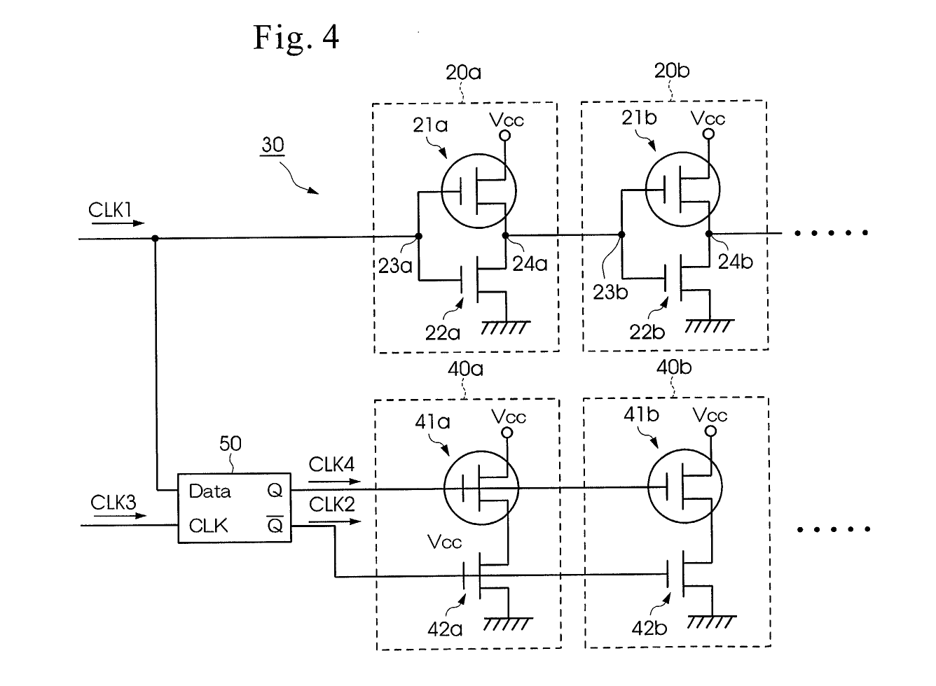

Next, other embodiments of this invention will be described with reference to FIGS. 3 and 4. FIG. 3 shows a configuration of an inverter circuit in accordance with a second embodiment of the invention, wherein parts identical to those shown in FIG. 1 are designated by the same reference numerals. Compared to the foregoing inverter circuit shown in FIG. 1, the inverter circuit 30 shown in FIG. 3 is characterized by the following points.

(i) The D flip-flop 50 provides an output terminal (Q) for producing a clock signal CLK4 based on the clock signals CLK1 and CLK3, so that the clock signal CLK4 is supplied to the gate electrodes of both PMOS transistors 41a and 41b of the switching circuits 40a and 40b. The clock signal CLK4 is an inversion of the foregoing clock signal CLK2 shown in FIG. 2C.

(ii) The prescribed power voltage (Vcc) is applied to the gate electrodes of both NMOS transistors 42a and 42b of the switching circuits 40a and 40b.

In the foregoing inverter circuit shown in FIG. 1, the PMOS transistors 41a and 41b of the switching circuits 40a and 40b function as load resistances. In the inverter circuit 30 shown in FIG. 3, the NMOS transistors 42a and 42b function as load resistances. The overall operation of the inverter circuit 30 shown in FIG. 3 is basically similar to the overall operation of the foregoing inverter circuit shown in FIG. 1. During the time period T2 between time t₁₄ and time t₁₅, both the PMOS transistors 41a and 41b are turned ON, so that switching currents flow through the PMOS transistors 41a and 41b as well as the NMOS transistors 42a and 42b respectively. Thus, it is possible to maintain the junction temperature tⱼ substantially at a constant value.

FIG. 4 shows a configuration of an inverter circuit in accordance with a third embodiment of the invention, wherein parts identical to those shown in FIGS. 1 and 3 are designated by the same reference numerals. The inverter circuit 30 shown in FIG. 4 is characterized in that the D flip-flop 50 provides both the output terminal (Q) and the inverted output terminal (\overline{Q}). That is, the inverter circuit 30 is characterized by the following points.

(i) The clock signal CLK4 output from the output terminal of the D flip-flop 50 is input to the gate electrodes of both PMOS transistors 41a and 41b of the switching circuits 40a and 40b.

(ii) The clock signal CLK2 output from the inverted output terminal of the D flip-flop 50 is input to the gate electrodes of both NMOS transistors 42a and 42b of the switching circuits 40a and 40b.

In the inverter circuit 30 shown in FIG. 4, when both PMOS transistors 41a and 41b are turned ON, both NMOS transistors 42a and 42b are correspondingly turned ON in the switching circuits 40a and 40b. In addition, when both PMOS transistors 41a and 41b are turned OFF, both NMOS transistors 42a and 42b are correspondingly turned OFF. The period of time in which all the PMOS transistors 41a and 41b and the NMOS transistors 42a and 42b are simultaneously turned ON matches the time period (e.g., T2) in which no current flows through the unit inverters 20a and 20b. Therefore, the inverter circuit of the third embodiment shown in FIG. 4 can demonstrate the same effects as the aforementioned inverter circuit of the second embodiment shown in FIG. 3.

This invention is not necessarily limited to the aforementioned embodiments; hence, it can be freely modified within the scope of the invention. All the embodiments are designed to use the D flip-flop 50 for generation of a clock signal (or clock signals) to be supplied to the switching circuits 40a and 40b. Such a clock signal supply is not necessarily limited to the D flip-flop 50. Hence, it is possible to use any other circuitry that is capable of providing the prescribed clock signal(s) to the switching circuits 40a and 40b when the clock signal CLK1 is not input to the unit inverters 20a and 20b.

In summary, this invention provides an inverter circuit that comprises unit inverters, switching circuits, and a clock signal supply. Herein, the switching circuits are arranged relative to the unit inverters respectively. The clock signal supply (e.g., D flip-flop) automatically supplies the prescribed clock signal to the switching circuits when no clock pulse is input to the unit inverters. Therefore, it is possible to obtain the outstanding effect that substantially no variations occur in the junction temperature and response time (jitter) even though the frequency of the clock signal input to the unit inverters is varied. Thus, the inverter circuit can operate in a stable manner regardless of variations of the frequency of the clock signal input to the unit inverters; hence, it is suitable for use in a highly accurate measuring device.

As this invention may be embodied in several forms without departing from the spirit or essential characteristics thereof, the present embodiments are therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

What is claimed is:

1. An inverter circuit comprising:
at least one unit inverter for inputting clock pulses;
at least one switching circuit; and
a clock signal supply for supplying a prescribed clock signal to the switching circuit when no clock pulse is input to the unit inverter.

2. An inverter circuit comprising:
a plurality of unit inverters that are connected together in a cascade connection manner and which input clock pulses;
a plurality of switching circuits that are arranged relative to the unit inverters respectively; and
a clock signal supply for supplying a prescribed clock signal to the switching circuits when no clock pulse is input to the unit inverters.

3. An inverter circuit according to claim 1 or 2, wherein the unit inverter inputs the clock pulses at variable frequencies.

4. An inverter circuit according to claim 1 or 2, wherein each of the unit inverter and the switching circuit comprises a pair of a PMOS transistor and an NMOS transistor.

5. An inverter circuit according to claim 4, wherein the PMOS transistor and the NMOS transistor contained in the switching circuit each have a prescribed size that is 1/n times smaller than the size of the PMOS transistor and the NMOS transistor contained in the unit inverter.

6. An inverter circuit according to claim 1 or 2, wherein a first clock signal (CLK1) having a variable frequency is input to the unit inverter comprising a pair of a PMOS transistor and an NMOS transistor, and a second clock signal (CLK3) having a constant frequency is input to the clock signal supply corresponding to a D flip-flop that supplies the prescribed clock signal (CLK2, CLK4) to the switching circuit comprising a pair of a PMOS transistor and an NMOS transistor.

7. An inverter circuit according to claim 6, wherein a gate electrode of the PMOS transistor of the switching circuit is grounded, and an inverted output of the D flip-flop is supplied to a gate electrode of the switching circuit.

8. An inverter circuit according to claim 6, wherein a prescribed power voltage (Vcc) is applied to a gate electrode of the NMOS transistor of the switching circuit, and an output of the D flip-flop is supplied to a gate electrode of the PMOS transistor of the switching circuit.

9. An inverter circuit according to claim 6, wherein an output of the D flip-flop is supplied to a gate electrode of the PMOS transistor of the switching circuit, and an inverted output of the D flip-flop is supplied to a gate electrode of the NMOS transistor of the switching circuit.
